(19) United States
(12) Patent Application Publication
(10) Pub. No.: US 2011/0084288 A1
(43) Pub. Date: Apr. 14, 2011

(54) Organic light emitting diode display and method of manufacturing the same

(76) Inventors: Moon-Jae Lee, Yongin-City (KR); Young-Hee Lee, Yongin-city (KR)

(21) Appl. No.: 12/923,732

(22) Filed: Oct. 6, 2010

(30) Foreign Application Priority Data
Oct. 8, 2009 (KR) 10-2009-0095830

(51) Int. Cl. H01L 33/08; H01L 33/00

(52) U.S. Cl. 257/88; 438/34; 257/E33.064; 257/E33.001

(57) ABSTRACT

An organic light emitting diode (OLED) display includes a substrate, a first electrode on the substrate, an emission layer on the first electrode, and a second electrode on the emission layer, the second electrode including a transflective conductive layer and a conductive oxide layer.

### BACKGROUND

1. Field

Example embodiments relate to an organic light emitting diode (OLED) display and a method of manufacturing the same.

2. Description of the Related Art

An OLED display emits light to realize an image. In particular, when electrons injected from one electrode of the OLED display are combined with holes injected from another electrode of the OLED display in an emission layer between the electrodes to generate excitons, energy may be released.

The OLED display is a self-emitting display, i.e., without a separate back light source, and may have low power consumption. The OLED display may include a plurality of pixels emitting red, blue, and green lights, and may realize a full color by combining them.

### SUMMARY

Embodiments are directed to an OLED display and a method of manufacturing the same, which substantially overcome one or more of the problems due to the limitations and disadvantages of the related art.

It is therefore a feature of an embodiment to provide an OLED display with an electrode structure capable of minimizing voltage drop and improving luminance uniformity.

It is therefore another feature of an embodiment to provide a method of manufacturing an OLED display with an electrode structure capable of minimizing voltage drop and improving luminance uniformity.

At least one of the above and other features and advantages may be realized by providing an OLED display, including a substrate, a first electrode formed on the substrate, an emission layer formed on the first electrode, and a second electrode formed on the emission layer. The second electrode may include a transflective conductive layer and a conductive oxide layer.

The conductive oxide layer may have a reflection coefficient ranging from about 1.5 to about 2.

The conductive oxide layer may have a thickness ranging from about 50 nm to about 150 nm.

The transflective conductive layer may be between the conductive oxide layer and the emission layer.

The conductive oxide layer may overlap an entire top surface of the transflective conductive layer.

The transflective conductive layer may include a first layer including aluminum (Al) and a second layer including silver (Ag).

The transflective conductive layer may have a thickness of about 50 nm or less.

The first electrode may be a cathode, while the second electrode may be an anode.

At least one of the above and other features and advantages may also be realized by providing a method of manufacturing an OLED display, including forming a first electrode on a substrate, forming an emission layer on the first electrode, and forming the second electrode on the emission layer. The step of forming the second electrode may include forming a transflective conductive layer and forming a conductive oxide layer.

The step of forming the conductive oxide layer may be performed in an oxygen partial pressure ratio ranging from about 0.5% to 10%.

The step of forming the conductive oxide layer may be performed by a facing target sputtering (FTS) method.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a cross-sectional view of an OLED display according to an embodiment.

### DETAILED DESCRIPTION

Korean Patent Application No. 10-2009-0095830, filed on Oct. 8, 2009, in the Korean Intellectual Property Office, and entitled: “Organic Light Emitting Diode Display and Method of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

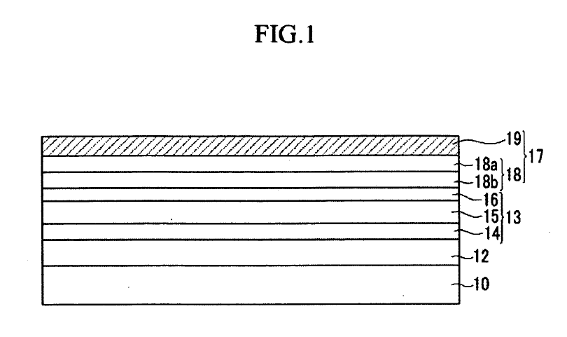

FIG. 1 illustrates a schematic cross-sectional view of an OLED display according to an embodiment. Referring to FIG. 1, the OLED display may include a substrate 10, a first electrode 12 formed on the substrate 10, an organic light emitting member 13 formed on the first electrode 12, and a second electrode 17 formed on the organic light emitting member 13.

The substrate 10 may be any suitable substrate. For example, the substrate 10 may include one or more of a glass substrate, a silicon wafer, a polymer film, and the like.

The first electrode 12 may be an anode or a cathode, and may be made of an opaque conductor. For example, the first electrode 12 may include one or more of aluminum (Al) or an aluminum alloy, silver (Ag) or a silver alloy, copper (Cu) or a copper alloy, and the like.

The organic light emitting member 13 may have a multi-layer structure including an emission layer 15 and auxiliary layers 14 and 16 for improving luminous efficiency of the emission layer 15.

The emission layer 15 may be made of an organic material expressing at least one of primary colors, e.g., red, green, and blue, or a mixture of organic materials and inorganic materials. The emission layer 15, for example, may include aluminum tris(8-hydroxyquinoline)(Alq3), anthracene, and a distryl compound. In general, an OLED display may realize an image by a diversity of combinations of primary colors coming from the emission layer.

The auxiliary layers 14 and 16 may include an electron transport layer (ETL) and a hole transport layer (HTL) for controlling balance of electrons and holes, and an electron injection layer (EIL) and a hole injection layer (HIL) for reinforcing injection of electrons and holes, which may be selected as a single layer or a plurality of layers.

The second electrode 17 may include a transflective conductive layer 18 and a conductive oxide layer 19.

The transflective conductive layer 18 may be made of a transflective conductive material that partly transmits light and partly reflects it, i.e., a material that may have various reflection and transmission degrees depending on its thickness. For example, the transflective conductive layer 18 may be a thin metal layer, and may include silver (Ag), aluminum (Al), gold (Au), nickel (Ni), magnesium (Mg), an alloy thereof, or a combination thereof.

The transflective conductive layer 18 may be thin in order to exhibit a transflective characteristic, e.g., the transflective conductive layer 18 may be thinner than the organic light emitting member 13. The transflective conductive layer 18 may have a single layer structure or a multi-layer structure. For example, the transflective conductive layer 18 may include first and second layers 18a and 18b, e.g., the second layer 18b may be between the first layer 18a and the conductive oxide layer 19. The first layer 18a may include aluminum (Al) or an aluminum alloy. The second layer 18b may include silver (Ag) or a silver alloy, e.g., the second layer 18b and the first layer 18a may completely overlap each other. A total thickness of the transflective conductive layer 18, e.g., a combined thickness of the first and second layers 18a and 18b, may be about 50 nm or less in order to exhibit a transflective characteristic.

The conductive oxide layer 19 may be made of a conductive oxide, e.g., a transparent conductive oxide (TCO). The TCO may include, e.g., one or more of ITO, IZO, ZnO, and the like. The conductive oxide layer 19 may be on, e.g., directly on, the transflective conductive layer 18, so the transflective conductive layer 18 may be between the conductive oxide layer 19 and the organic light emitting member 13.

An arrangement of the conductive oxide layer 19 on the transflective conductive layer 18 may compensate for the low thickness of the transflective conductive layer 18, thereby reducing surface resistance of the second electrode 17. In detail, as the transflective conductive layer 18 is a metal layer with a low thickness, i.e., in order to have a transflective characteristic, its surface resistance may increase, thereby potentially causing a voltage drop in an OLED display with a large area. However, since the conductive oxide layer 19, according to an embodiment, may be disposed on the transflective conductive layer 18 to compensate for the low thickness of the transflective conductive layer 18, increase of the electrode resistance and voltage drop may be prevented. Accordingly, the structure of the conductive oxide layer 19 on the transflective conductive layer 18 may improve luminance uniformity of an OLED display with a large area.

The conductive oxide layer 19 may have a thickness of about 50 nm to about 150 nm, e.g., the thickness of the conductive layer 19 may be larger than that of the transflective conductive layer 18. When the conductive oxide layer 19 has a thickness within the above range, voltage drop of the OLED display device may be reduced and a desired transmittance may be secured.

The conductive oxide layer 19 may have a reflection coefficient of about 1.5 to about 2. When the reflection coefficient is within the above range, an OLED display may exhibit a microcavity characteristic. It is noted that the microcavity characteristic refers to repetitively reflecting light between a reflective layer and a transflective layer positioned at a predetermined interval, and amplifying a predetermined wavelength of light while turning off the other wavelengths due to strong interference effects. The microcavity characteristic may improve luminosity of the OLED display. For example, as the red, blue, and green lights emitted from various pixels in the OLED display may have different luminous efficiencies, e.g., a material having low luminous efficiency may not realize a desired color coordinate either of a single color or in combination of colors realizing a white light, the microcavity characteristic may improve luminance efficiency and uniformity of all lights.

The conductive oxide layer 19 may cover, e.g., completely cover, an upper surface of the transflective conductive layer 18, e.g., an upper surface of the first layer 18a facing away from the organic light emitting member 13. Therefore, the conductive oxide layer 19 may prevent or substantially minimize metal of the transflective conductive layer 18 from directly contacting with air. Accordingly, the conductive oxide layer 19 may prevent or substantially minimize degradation of metal in the transflective conductive layer 18 due to oxygen or moisture in the air. As a result, the conductive oxide layer 19 may prevent the transflective conductive layer 18 from having increased resistance, while simultaneously increasing life-span of the OLED display.

The OLED display may have an inverted structure, i.e., where the first electrode 12 is a cathode and the second electrode 17 is an anode.

Hereinafter, a method of manufacturing the OLED display will be described with reference to FIG. 1.

Referring to FIG. 1, the first electrode 12 may be formed on the substrate 10. For example, the first electrode 12 may be formed by a sputtering method.

Next, an organic light emitting member 13 may be sequentially laminated on the first electrode 12. The organic light emitting member 13 may be disposed by a deposition or an inkjet printing method.

Then, a transflective conductive layer 18 including the first and second layers 18a and 18b may be formed on the organic light emitting member 13 by sequentially laminating aluminum (Al) and silver (Ag) on the organic light emitting member 13. The transflective conductive layer 18 may have a total thickness, i.e., a distance as measured between an uppermost surface of the organic light emitting member 13 and a bottommost surface of the conductive oxide layer 19, of about 50 nm or less. For example, a combined thickness of the first and second layers 18a and 18b may be about 50 nm or less.

Next, the conductive oxide layer 19 may be formed on, e.g., directly on, the transflective conductive layer 18, e.g., to cover an entire upper surface of the transflective conductive layer 18. The conductive oxide layer 19 may be formed at a relatively low temperature, so potential damage to the upper surface of the transflective conductive layer 18 may be substantially minimized. Further, the conductive oxide layer 19 may prevent or substantially minimize thermal degradation of the organic light emitting member 13. For example, the conductive oxide layer 19 may be formed, e.g., by a facing target sputtering (FTS) method, at a substrate temperature of, e.g., about 80 ° C. or lower. In another example, the conductive oxide layer 19 may be formed under an oxygen partial pressure ratio ranging from about 0.5% to about 10%, and may have a work function ranging from about 4.2 eV to about 5.2 eV.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An organic light emitting diode (OLED) display, comprising:
a substrate;
a first electrode on the substrate;
an emission layer on the first electrode; and
a second electrode on the emission layer, the second electrode including a transflective conductive layer and a conductive oxide layer.

2. The OLED display as claimed in claim 1, wherein the conductive oxide layer has a reflection coefficient of about 1.5 to about 2.

3. The OLED display as claimed in claim 1, wherein the conductive oxide layer has a thickness of about 50 nm to about 150 nm.

4. The OLED display as claimed in claim 1, wherein the transflective conductive layer is between the conductive oxide layer and the emission layer.

5. The OLED display as claimed in claim 4, wherein the conductive oxide layer overlaps an entire top surface of the transflective conductive layer.

6. The OLED display as claimed in claim 1, wherein the transflective conductive layer includes a first layer and a second layer, the first layer including aluminum (Al), and the second layer including silver (Ag).

7. The OLED display as claimed in claim 6, wherein the transflective conductive layer has a total thickness of about 50 nm or less.

8. The OLED display as claimed in claim 1, wherein the first electrode is a cathode, and the second electrode is an anode.

9. A method of manufacturing an organic light emitting diode (OLED) display, comprising:
forming a first electrode on a substrate;
forming an emission layer on the first electrode; and
forming a second electrode on the emission layer, such that the second electrode includes a transflective conductive layer and a conductive oxide layer.

10. The method as claimed in claim 9, wherein forming the conductive oxide layer is performed under an oxygen partial pressure ratio of about 0.5% to about 10%.

11. The method as claimed in claim 9, wherein forming the conductive oxide layer is performed by a facing target sputtering (FTS) method.
